(19) United States
(12) Patent Application Publication
(10) Pub. No.: US 2004/0052064 A1
(43) Pub. Date: Mar. 18, 2004

(54) Electromagnetic shielding and cooling device for printed circuit board

(76) Inventors: Michael J. Oliver, McDonald, PA (US); James E. Kline, Blairstown, NJ (US)

Correspondence Address: Gerald Levy, Pitney Hardin Kipp & Szuch, 19th Floor, 685 Third Avenue, New York, NY, 10017-4024, US

(21) Appl. No.: 10/416,872

(22) PCT Filed: Nov. 15, 2001
(86) PCT No.: PCT/US01/46122

(51) Int. Cl. H05K 9/00

(52) U.S. Cl. 361/816

(57) ABSTRACT

An electromagnetic shield includes an electrically conductive contact strip arranged to form a perimeter fence. The contact strip used to form the shielding fence is oriented such that the contact fingers are vertical to the printed circuit board and the spring fingers face inward toward a heat producing device. A shielding lid, which also functions as a heat sink for cooling the device, makes electrical contact around the perimeter thereof by sliding down across the contact portions of each finger of the fence, and thereby coming to rest on the heat producing device, either directly or through a thermally conductive interface. A spring clip which holds the heat sink in place over the heat producing device is designed to clip into opposite sides of the perimeter fence below the row of spring fingers, thereby forming a unitary shielding and cooling device.

This application claims priority of U.S. provisional patent application serial No. 06/248,203, entitled “Electromagnetic Shielding and Cooling Device for Printed Circuit Board”, filed on Nov. 15, 2000.

### FIELD OF INVENTION

The present invention relates generally to shielding devices for minimizing electromagnetic and radio frequency interference emissions and susceptibility effects on electrical and electronic devices, and more particularly, to a shielding and cooling device that is easily formed to a desired size and shape.

### DESCRIPTION OF THE PRIOR ART

It is highly desirable to provide shielding for electronic components found in radio transmitters, radio receivers, computers and other electronic devices that use circuitry that emits or is susceptible to electromagnetic radiation. It is known that these components can be shielded to reduce undesirable electromagnetic interference (EMI), radio frequency interference (RFI), and/or susceptibility effects with the use of a conductive enclosure that reflects or absorbs electromagnetic energy. A variety of known prior art shielding enclosures are mounted directly upon a printed circuit board and envelope one or more electronic components, as shown, for example, in U.S. Pat. No. 5,633,786, the contents of which are hereby incorporated by reference. Such enclosures are typically box-like structures that are open on the side that mates with the circuit board. The perimeter or the open side of the enclosure is typically soldered to pats on the circuit board provided for this purpose. The solder pads are connected to an internal layer of conductive metal which acts as a side of the shielding enclosure. These devices have been utilized for shielding electronic components in the market, but the high manufacturing costs associated therewith have impeded the success thereof. That is, since the devices are not adjustable in size or in shape, and they usually come in predetermined sizes, a multitude of tools have been required for manufacturing the multitude of sizes, thereby increasing cost.

A variety of known prior art shielding devices for components provided on printed circuit boards are frequently included within the same frame or packaging that supports the component being shielded. In order to minimize the size of the component package, the shields are sometimes arranged close to the components being shielded. The shielding enclosure itself may impede effective heat transfer by restricting airflow and by reflecting radiant energy back into the component. The close arrangement of the shield to the components merely compounds this problem and further proves the need for an additional cooling mechanism to be provided.

For example, U.S. Pat. No. 5,566,052 to Hughes discloses an electronic device with an EMI shield surrounding an electronic, component on a substrate. The shield comprises four side walls extending over at their tops to form an inverted resiliently flexible U-bend for receiving the top wall. The lower free ends of the side walls are provided with downward securing pins which thereby secure the shield to the printed circuit board by passage into through holes. The material of the shield is sufficiently resilient so that the U-shaped bends provide a degree of resilience to allow for resilient flexing movement between the top wall of the shield and each of the side walls. The top wall is formed with a central aperture and is surrounded by a plurality of cutting teeth extending into the aperture. Each of the teeth has a cutting edge which is inclined downwardly into the chamber defined within the shield. The device also includes a heat sink defined by a center body having a plurality of surrounding heat exchange fins extending from the body in positions axially based therealong. The heat sink is placed with its lower end region extending into the aperture. The heat sink is pushed downwardly into the aperture and during this process the end of the cutting. edges cut axial grooves in the end region of the heat sink. The heat sink is then rotated within the aperture in an appropriate direction to cause the teeth to dig into the end region while creating a spiral cut in the end region towards a flange. This rotation of the heat sink accompanied by the spiral cutting action results in movement of the teeth themselves towards the flange by a flexing action upon the top wall. The effect of such an action is that the teeth tend to move towards the plane of the top wall and cause a resilient flexure of the shield at the U-bends. The upward movement of the teeth is accommodated mainly by the resilient flexure of the U-bends, which are resiliently deformed towards a shallow condition from a deeper condition.

Further, U.S. Pat. Nos. 5,241,453 and 5,357,404 to Bright et al. disclose EMI shielding devices having a frame including a first pair of parallel side walls and a second pair of parallel side walls. Each of the side walls has a plurality of resilient cantilevered beams projecting obliquely outward from the plane of the frame walls for contacting a heat sink. The heat sink includes a plurality of cooling towers projecting outwardly and upwardly from the base thereof, as well as four dependent skirts which extend downwardly from all four sides of the base. The device further includes retainers made from a material such as phosphor bronze which are shaped to provide a spring characteristic such that when latched to. a latching detent they hold the heat sink tightly against the top of the electronic package. The heat sink is placed over the electronic package, with a thin thermal interface placed there between, and with the four skirts extending downward outside the side walls of the frame and engaged by resilient contacting beams. The engagement between the skirts and the beams thereby grounds the heat sink to the ground circuit of the substrate. The heat sink retainers are in the form of a resilient strap which is secured at one end to the upper side of the base. Since the retainers pass through the heat sink inside of the frame, depending skirts can be provided on all sides of the heat sink to thus provide shielding of the electronic package on all sides, not only by the frame but also by the sink skirt.

Such prior art shielding and heat sink devices are generally manufactured for a specific component, thus requiring special features on the shielding enclosure and/or the heat sink for support thereof.

### SUMMARY OF THE INVENTION

The present invention overcomes the disadvantages of the prior art by providing a shielding and cooling device including a shielding fence having a plurality of contact fingers for engaging a shielding and heat sink lid secured within the fence perimeter, and a slot or opening disposed on at least two opposing side walls of the fence for receiving an end part of at least one spring clip. The spring clip secures the heat sink and the shielding fence as a unitary shielding and cooling device when disposed on a printed circuit board.

### BRIEF DESCRIPTION OF THE DRAWINGS

These, and other, objects, features and advantages of the present invention will become more readily apparent to those skilled in the art upon reading the following detailed description, in conjunction with the appended drawings, in which:

FIG. 1 is a perspective view of an electromagnetic shielding and heat sink device for a printed circuit board in accordance with the present invention;

FIG. 2 is an exploded view thereof when positioned for attachment to the printed circuit board;

FIG. 3 is a side view of the shielding fence shown in FIG. 1 when in a flat state;

FIG. 4 is a top view of the shielding fence shown in FIG. 1;

FIG. 5 is a cross-sectional view taken along line 5-5 in FIG. 4; and

FIG. 6 is an enlarged view of Detail A shown in FIG. 5.

### DETAILED DESCRIPTION OF THE PREFERRED EMBODIMENTS

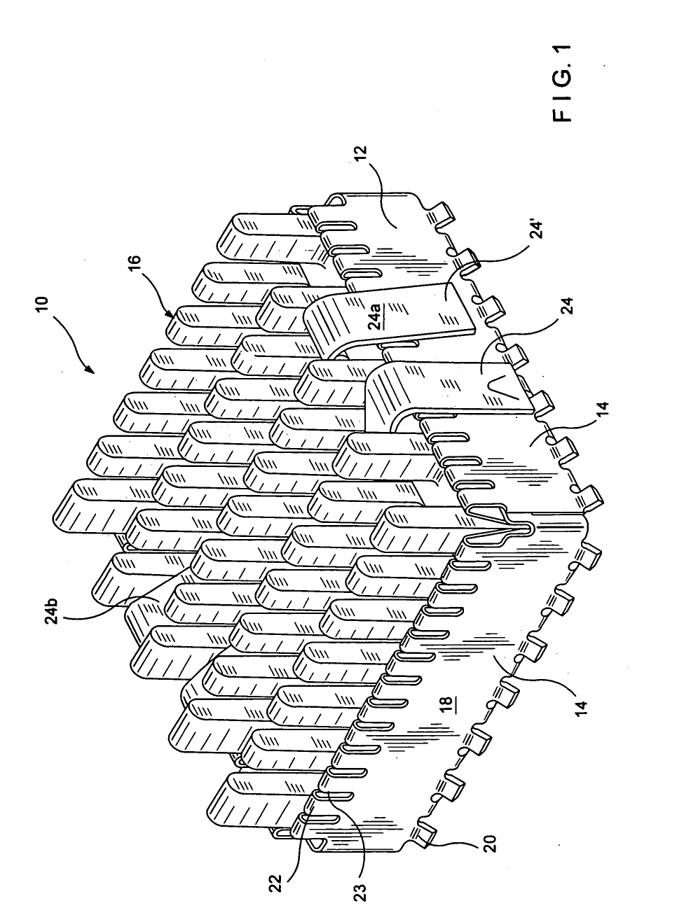

Referring to FIGS. 1 and 2, an electromagnetic shielding and cooling device for a printed circuit board in accordance with the present invention is shown generally by reference numeral 10. Shielding device 10 is designed to be welded, soldered, or otherwise fixed to a printed circuit board (PCB) 11 and thereby encompass and shield one or more underlying electronic components 26 that are mounted on the printed circuit board. The electromagnetic shielding device 10 can be used to shield either a section or component of a printed circuit board or the entire board.

Shielding device 10 includes a perimeter fence 12, preferably fabricated from a contact strip having a plurality of contact fingers 22, and a shielding lid 16 which also functions as a heat sink or cooling device. The heat sink 16 is secured to the perimeter fence 12 in a preferred embodiment of the invention by at least one retention spring 24 and preferably, two retention springs 24, 24′. Alternatively, a thermally conductive double sided adhesive pad can be provided between the shielding lid and the heat producing device. The shielding device is preferably flush or surface mounted by soldering or welding, or it can be through-mounted to printed circuit board 11 so as to cover at least one heat and EMI/RFI sensitive and/or EMI/RFI producing component 26, such as, for example, an integrated circuit. Generally, it is preferred to dispose a conformable heat transfer Dad or thermal interface 28 between the component 26 and the shielding lid 16, as explained in greater detail below.

The perimeter fence 12 is defined by the bending of the contact strip to form a plurality of side walls 14 which are joined together at a seam by welding or other known fastening means. If desired, the walls 14 could be formed into any reasonable configuration. However, in the preferred embodiment, the walls 14 are formed into a square, rectangle or other quadrilateral shape. By using the walls 14 in the form of a rectangle or square, the configuration of the heat sink 16 is simplified along with a simplification of mounting the walls 14 on a conventional printed circuit board. It is also possible that each of the side walls 14 can be made from a separate contact strip of material, with the corners being fastened together, if desired, in a known manner. The side walls 14 of the perimeter fence 12 are preferably made from a dual thickness spring material, such as, for example, a milled beryllium copper strip. As shown in FIG. 6, a dual thickness material is used such that a lower half 30 of each of the side-walls 14 has a greater thickness than the upper half 32 of each of the side walls 14. According to a preferred embodiment of the present invention, the lower half 30 is approximately two times as thick as the upper half 32. More specifically, the lower half 30 has a thickness of 0.010 inches (0.025 cm) and the thickness of the upper half 32 is 0.005 inches (0.013 cm). The advantage of using a dual thickness material is that the resultant perimeter fence 12 is relatively stiff and can thus be prevented from bowing or otherwise distorting in the middle of a long span of the side wall 14. On the other hand, the upper half 32 of the side wall 14 having a lesser thickness allows the contact fingers 22 to remain resilient for appropriate contact and deflection when engaged with the shielding lid cooling device 16. Other strip configurations could of course also be used to form the perimeter fence 12. Such strips could be, for instance, readily available contact strips having convex spring fingers, the curvature of which is sufficiently resilient to secure the shielding lid cooling device 16 when the convex surfaces of the spring fingers are vertically oriented and facing inward towards the heat producing component 26. Other materials could be used as well, including electrically conductive materials and other metals such as tin plated phosphor bronze and other alloys of copper depending upon the required shielding. In particular, however, it is desirable that the material be metals that are capable of being readily soldered or welded and capable of low resistance electrical conductivity. If the primary purpose of the shield is to reduce magnetic field interference, it is generally preferable to use a steel or other alloy which has a relatively high permeability at low frequencies. To provide electrical conductivity on materials with relatively high resistance, the material may be plated with a low resistance metal, such as tin. If the principal concern is to reduce electrical field interference, then it is generally preferable to use a copper alloy as will be readily apparent to one skilled in the art of electromagnetic shielding.

Each of the side walls 14 includes a side member portion 18 and one or more serrations 20 extending from a lower edge of the side member portion 18. Each of the side walls 14 further includes a plurality of contact fingers 22 which are separated by a plurality of slots 23, the configuration of the contact fingers 22 being best shown in FIG. 6. The contact fingers 22 are preferably formed generally by bending over the upper half 32 of the side wall 14 so as to form a generally U20 shaped, inwardly projecting element. The compliant and resilient nature of the contact fingers 22 is beneficial for retaining the cooling device 16 within the perimeter fence 12 and for tolerating any surface irregularity or dimensional variations which may occur in the cooling device 16.

The serrations 20 are preferably alternately offset 5 such that one serration 20a bends outwardly from the fence 12 and an adjacent serration 20b bends inwardly from the fence 12 toward the component 26. As best illustrated in FIG. 6, the offset serrations 20a, 20b provide a stabilizing foot. for soldering or welding the device 10 to the printed circuit board and for increasing the lateral stability of the perimeter fence 12. Through-hole mounting or any other type of known mounting arrangement could also be utilized for securing device 10 to the printed circuit board 11. In this regard, the device 10 of the present invention is adaptable for tape and reel packaging for use in standard automated pick and place equipment or, alternatively, the device of the present invention may be packed in trays for correct orientation within an automated system or, still further, they may be packed in bulk as may be required by conventional equipment.

The shielding and cooling lid 16 preferably formed from extruded aluminum, however, any material capable of functioning as a heat sink and which is compatible with the material of the perimeter fence 12 could also be used, such as, for example, tin plated copper. The cooling device 16 preferably includes a base surface 34 and a plurality of fins 36 projecting upwardly therefrom. The lid 16 makes electrical contact around its perimeter by sliding down across the projecting elements defining the contact fingers 22 and coming to rest on the heat producing component 26. The base surface 34 is either directly in contact with the component 26 or indirectly in contact therewith through the heat transfer pad 28 which is disposed above the heat sensitive component 26. The heat transfer pad 28 is formed from a thermally conductive interface material such as thermally conductive rubber, tape, or gel. Thus, the present invention provides conductive cooling from the component 26 to the cooling device 16 as well as radiant and convective cooling which occurs due to the presence of the cooling fins 36.

Retention springs 24, 24′ each include depending legs 24a and an arcuate center portion 24b extending therebetween. The retention springs 24, 24′ further include an inwardly extending clip element 38 which is retained by an opening 40 disposed in the side member portion 18 of at least two opposing side walls 14. Referring to FIG. 1, the clip element 38 is illustrated in an engaged position on the retention spring 24, whale the other retention spring 24′ is in a disengaged or unclipped position. It should be apparent to one skilled in the art that while two retention springs are shown, a single retention spring or more than two retention springs could be utilized instead. More specifically, for larger shielding devices requiring more retention force due to the size and weight of the cooling device, the retention springs may clip into position on all four side of the shielding device or into multiple openings on two opposing side.

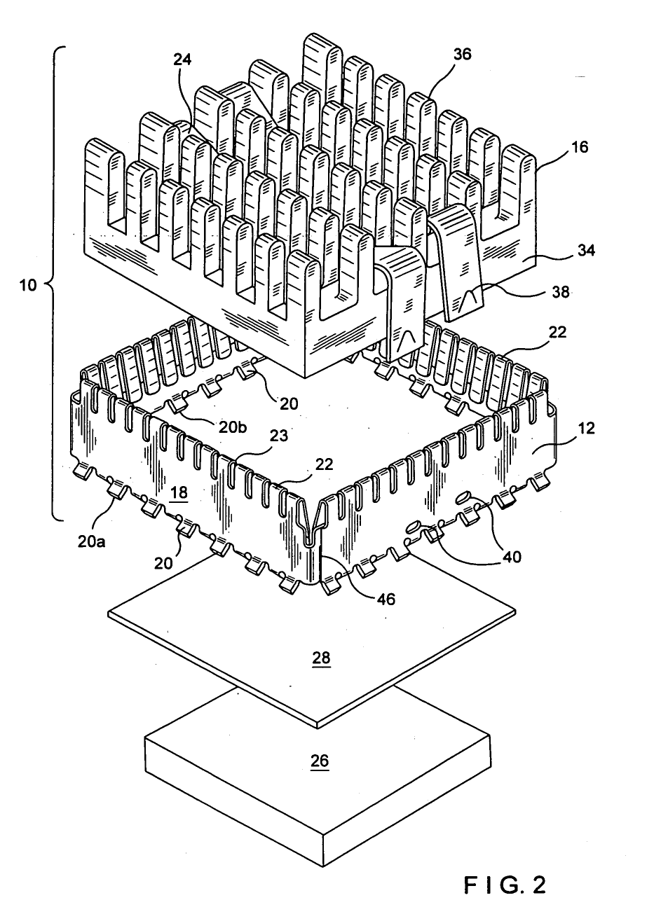

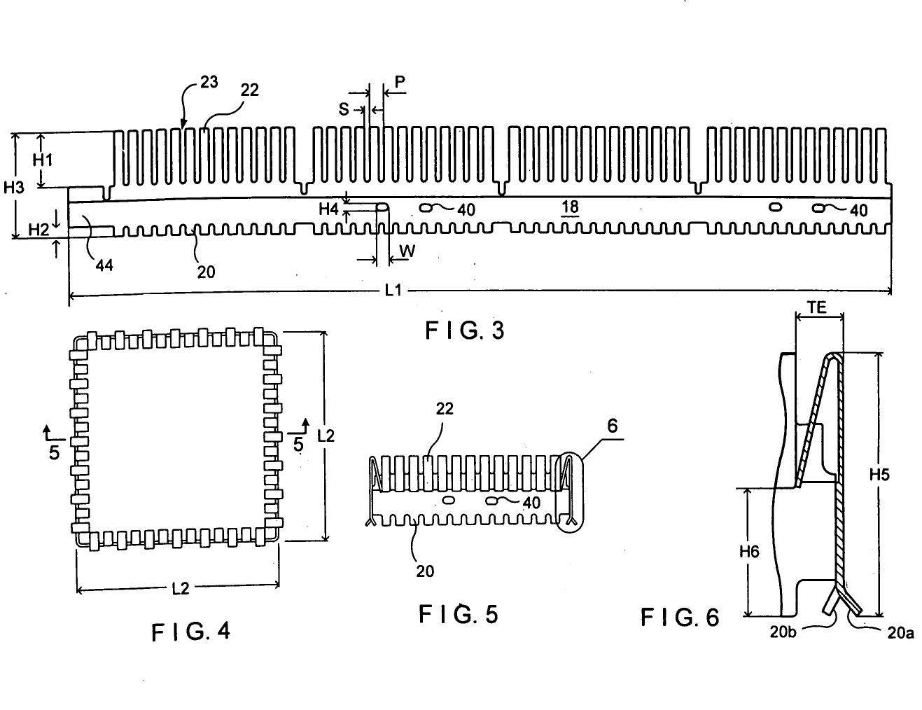

Referring to FIG. 3, the perimeter fence 12 is 20 illustrated in an open position before being bent to form the side walls 14. As illustrated, blanks 42 are preferably disposed at spaced locations in order to facilitate bending of the perimeter fence 12 to form a corner of an enclosure. That is, there is no contact finger 22 present at certain instances so that the fence 12 may be more readily bent as desired. In a preferred embodiment, the perimeter fence 12 further includes a welding tab 44 which is joined with the opposing end of the fence 12 and secured thereto in a welded lap joint 46 so as to close the fence 12 and form an enclosure having the desired configuration.

Referring to FIGS. 3-6, the following specific dimensions are provided as an example of one manner in which the shielding device 10 may be constructed in accordance with the present invention. It will be apparent to one skilled in the art that such dimensions are not limiting and may be modified as desired depending on the component(s) to be shielded and the specific shielding and cooling application of the device in one preferred embodiment of the present invention, the perimeter fence 12 has a total flat length L1 of approximately 4.35 inches. This length covers 58 pitches (P) including six blank fingers. The pitch P of the illustrated perimeter fence is 0.075 inch (0.19 cm), and the slot 23 defines a space S between adjacent contact fingers 22 of 0.025 inch (0.064 cm). The contact fingers 22 have a height H1 from the side member, portion 18 of approximately 0.275 inch and the serrations 20 have a depending height H2 from the side member portion 18 of approximately 0.025 inch. The overall height H3 of the perimeter fence 12 is approximately 0.474 inch. The openings 40 in the side member portion 18 have a preferred width W of 0.06 inch and a preferred height H4 of 0.035 inch. Preferably, the centerline of the openings 40 are positioned so as to coincide with the centerline of a corresponding slot 23 between adjacent contact fingers 22. When bent to form a square configuration in accordance with the illustrated embodiment, the length L2 of each of the side walls 14 is approximately 1.067 inch. Referring to FIG. 6, the offset serrations 20 are appropriately bent to form an approximately seventy degree angle therebetween and to form the desired foot for the perimeter fence 12. The finished fence 12 thus has an overall height H5 of approximately 0.28 inch, the lower half 30 having a height H6 of 0.108 inch corresponding to the portion of the side wall 14 which is formed with a thicker material. The upper half 32 of the side wall 14 is inverted in a U-shape configuration so as to form the contact fingers 22. In a preferred embodiment, a 5 terminal end of the contact finger is projecting a distance TE of approximately 0.065 inch inwardly from the side wall 14 and forms an angle therewith of approximately 67°.

The present invention thus provides an economical 10 and easily installed mechanism for providing both shielding and cooling to a electronic component such as an integrated circuit.

While the present invention has been described with preferred embodiments, it is to be understood that variations and modifications may be resorted to as will be apparent to those skilled in the art. Such variations and modifications are to be considered within the purview and the scope of the present invention.

What is claimed is:

1. An electronic shielding device including:
a shielding fence including a plurality of contact fingers;
a heat sink engaging said plurality of contact fingers and secured within said shielding fence; and
an attachment device for securing said heat sink to said shielding fence.

2. The electronic shielding device of claim 1 wherein said shielding fence defines a perimeter.

3. The electronic shielding device of claim 2 wherein said shielding fence is fabricated from a contact strip.

4. The electronic shielding device of claim 3 wherein said attachment device is at least one retention spring.

5. The electronic shielding device of claim 3 wherein said attachment device comprises a plurality of retention springs.

6. The electronic shielding device of claim 5 wherein said heat sink device forms a lid spanning said perimeter.

7. The electronic shielding device of claim 6 wherein said shielding fence is constructed and arranged to be surface mounted to a printed circuit board thereby covering at least one electronic component and providing EMI/RFI shielding.

8. The electronic shielding device of claim 7 wherein said shielding fence further provides a heat sink for at least one electronic component.

9. The electronic shielding device of claim 8 wherein said shielding fence is fabricated from a contact strip.

10. The electronic shielding device of claim 9 wherein said shielding fence is provided in a linear configuration and thereafter shaped to define said perimeter.

11. The electronic shielding device of claim 10 wherein said shielding fence is formed from a dual thickness spring material wherein a lower half of said shielding fence is formed from said spring material with a greater thickness than a thickness of said spring material forming an upper half of said shielding fence.
